(19) United States
(12) Patent Application Publication
(10) Pub. No.: US 2011/0142579 A1
(43) Pub. Date: Jun. 16, 2011

(54) TRANSFER DEVICE AND TARGET OBJECT PROCESSING APPARATUS INCLUDING SAME

(75) Inventors: Hiromitsu SAKAUE, Nirasaki City (JP); Masahito OZAWA, Nirasaki City (JP); Yoji IIZUKA, Hsin-chu (TW)

(73) Assignee: TOKYO ELECTRON LIMITED, Tokyo (JP)

(21) Appl. No.: 12/969,056

(22) Filed: Dec. 15, 2010

(30) Foreign Application Priority Data
Dec. 16, 2009 (JP) 2009-284823

(51) Int. Cl. H01L 21/677

(52) U.S. Cl. 414/222.13

(57) ABSTRACT

A transfer device includes a first transfer mechanism including a first shaft which is rotatable and vertically arranged and a horizontally extensible and retractable first arm having at a leading end thereof a first pick for holding a processing target object, the first arm being attached to the first shaft; and a second transfer mechanism including a second shaft which is rotatable and vertically arranged and a horizontally extensible and retractable second arm having at a leading end thereof a second pick for holding a processing target object, the second arm being attached to the second shaft. The first and the second transfer mechanism are vertically separated from each other while a rotation center of the first shaft and a rotation center of the second shaft coincide with each other.

### CROSS-REFERENCE TO RELATED APPLICATIONS

This application claims priority to Japanese Patent Application No. 2009-284823 filed on Dec. 16, 2009, the entire contents of which are incorporated herein by reference.

### FIELD OF THE INVENTION

The present invention relates to a transfer device and a target object processing apparatus including the transfer device.

### BACKGROUND OF THE INVENTION

In a manufacturing process of an electronic device, a processing target object is used, and various processes such as film formation, etching and the like are performed on the target object. For example, in a manufacturing process of a semiconductor integrated circuit device apparatus, a semiconductor wafer is used as the target object, and various processes such as film formation, etching and the like are performed on the semiconductor wafer. In general, such processes are carried out in separate processing apparatuses. For example, a film forming process is performed in a film forming apparatus having a film forming chamber, while an etching process is performed in an etching processing apparatus having an etching processing chamber.

Recently, in order to achieve a processing integration and reduce the foot print that is caused by an increase in the number of the processing apparatus, there has been widely used a multi chamber (cluster tool) type processing apparatus for processing a processing target object in which a plurality of processing chambers is disposed around a transfer chamber. A typical example of the multi chamber type processing apparatus for processing a processing target object is described in, e.g., Japanese Patent Application Publication No. 2005-64509 (corresponding to U.S. Patent Publication No. 20050036855).

Further, Japanese Patent Application Publication Nos. 2005-64509 and 2004-282002 (corresponding to U.S. Patent Publication No. 20090169344) describe a transfer device using a multi-joint robot that is used for transferring the target object between the transfer chamber and the processing chambers.

Meanwhile, in various processes such as film formation, etching and the like, extensive efforts have been devoted to reduce the processing time in order to increase the productivity.

However, once the reduction in the processing times of the respective processes is achieved, a rate control factor for the time required for overall processing of a processing target object in the multi chamber type apparatus is changed from the process rate control to the transfer rate control. For that reason, even if each of the processing times is substantially reduced, the increase in the productivity is limited.

### SUMMARY OF THE INVENTION

In view of the above, the present invention provides a transfer device having a simple structure and capable of solving the problem in which the increase in the productivity is limited even if the processing time in the processing apparatus is reduced and a target object processing apparatus including the transfer device.

In accordance with an aspect of the present invention, there is provided a transfer device including: a first transfer mechanism including a first shaft which is rotatable and vertically arranged and a horizontally extensible and retractable first arm having at a leading end thereof a first pick for holding a processing target object, the first arm being attached to the first shaft; a second transfer mechanism including a second shaft which is rotatable and vertically arranged and a horizontally extensible and retractable second arm having at a leading end thereof a second pick for holding a processing target object, the second arm being attached to the second shaft, wherein the first and the second transfer mechanism are vertically separated from each other while a rotation center of the first shaft and that of the second shaft coincide with each other.

In accordance with another aspect of the present invention, there is provided a target object processing apparatus for processing a target object, which employs the transfer device described above to transfer the target object.

### BRIEF DESCRIPTION OF THE DRAWINGS

The objects and features of the present invention will become apparent from the following description of embodiments, given in conjunction with the accompanying drawings, in which:

FIG. 1 is a top view schematically showing an example of a target object processing apparatus including a transfer device in accordance with a first embodiment of the present invention;

FIG. 2 is a cross sectional view schematically showing an example of the transfer device in accordance with the first embodiment of the present invention;

FIGS. 3A and 3B are top views showing an arm in a retracted state and an arm in an extended state, respectively;

FIGS. 4A and 4B are top views showing an arm in a retracted state and an arm in an extended state, respectively;

FIGS. 5A to 5F are top views, each showing an example of adjusting an angle between picks and directions of the picks;

FIGS. 6A to 6H are top views, each showing an example of a target object transferring method that can be performed by the transfer device in accordance with the first embodiment of the present invention;

FIG. 7 is a timing diagram of an example showing the target object transferring method that can be performed by the transfer device in accordance with the first embodiment of the present invention;

FIG. 8 is a cross sectional view for explaining a state in which an upper transfer mechanism of the transfer device is attached to a top plate of the transfer chamber;

FIG. 9 is a cross sectional view schematically showing an example of a transfer device in accordance with a second embodiment of the present invention;

FIG. 10 is a side view showing a fragmentary cross section of an example of a sliding mechanism;

FIG. 11 is a side view showing a fragmentary cross section of an example in which a column is used as a positioning member;

FIGS. 12A to 12C are side views showing fragmentary cross sections of an example in which the column is used as a distance adjustment member;

FIG. 13 is a cross sectional view schematically showing another example of the transfer device in accordance with the second embodiment of the present invention;

FIG. 14 is a cross sectional view schematically showing an example of a transfer device in accordance with a third embodiment of the present invention;

FIG. 15A is a side view in a normal state, and FIG. 15B is a top view in the normal state; and

FIG. 16A is a side view in a power failure state, and FIG. 16B is a top view in the power failure state.

### DETAILED DESCRIPTION OF THE EMBODIMENTS

Embodiments of the present invention will be described with reference to the accompanying drawings which form a part hereof. Further, like reference numerals will be given to like parts throughout all the drawings.

### First Embodiment

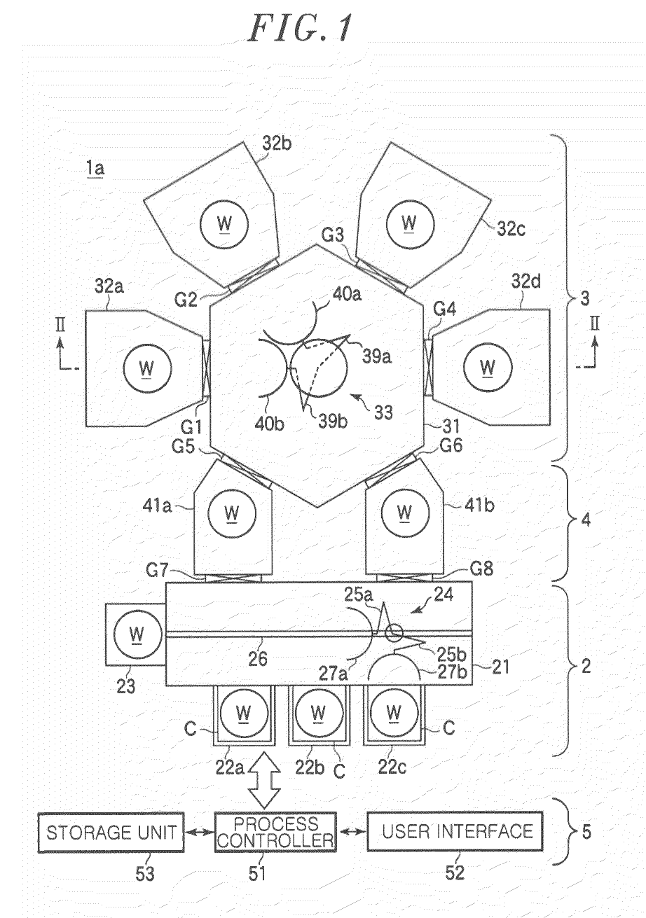

In this example, a multi chamber (cluster tool) type semiconductor manufacturing apparatus using a semiconductor wafer as a processing target object is employed as an example of an apparatus for processing the target object, as shown in FIG. 1.

As shown in FIG. 1, a semiconductor manufacturing apparatus 1a includes a loader module 2 for loading and unloading the semiconductor wafer W by transferring it between the semiconductor manufacturing apparatus 1a and the outside, a processing unit 3 for processing the wafer W, a load-lock unit 4 for loading and unloading the wafer W transferred between the loader module 2 and the processing unit 3, and a control unit 5 for controlling the semiconductor manufacturing apparatus 1a.

The loader module 2 has a loader unit 21. The pressure inside the loader unit 21 can be controlled to be set to the atmospheric pressure or close to the atmospheric pressure, e.g., a slight positive pressure with respect to the outside atmospheric pressure. In this example, the loader unit 21 is of a rectangular shape when seen from the top, the rectangular shape having longer sides and shorter sides perpendicular to the longer sides. The processing unit 3 is disposed to face one of the longer sides of the rectangle via the load-lock unit 4. One or more loading ports 22, each for mounting thereon a carrier C which is either accommodating wafers W therein or empty, are provided at the other one of the longer sides. In this example, three loading ports 22a to 22c are provided. The number of the loading ports 22 is not limited to three and can be varied. Each of the loading ports 22a to 22c is provided with a shutter (not shown). When the carrier C is mounted on one of the loading ports 22a to 22c, the shutter is opened so that the inner space of the carrier C and that of the loader unit 21 can communicate with each other while preventing intrusion of air from outside. An orienter 23 for aligning the direction of the wafers W unloaded from the carrier C is provided at a shorter side of the rectangle.

The processing unit 3 includes a transfer chamber 31 and a plurality of processing chambers 32 for processing the wafers W. In this example, a single transfer chamber 31 and four processing chambers 32a to 32d arranged around the transfer chamber 31 are provided. Each of the processing chambers 32a to 32d is configured as a vacuum chamber having an inner space that can be evacuated to a predetermined vacuum level, and a processing such as film formation, etching or the like can be performed therein. The processing chambers 32a to 32d are connected to the transfer chamber 31 through gate valves G1 to G4, respectively.

The load-lock unit 4 has a plurality of load-lock chambers 41. In this example, two load-lock chambers 41a and 41b are arranged around the single transfer chamber 31. Each of the load-lock chambers 41a and 41b is configured as a vacuum chamber having an inner space that can be evacuated to a predetermined vacuum level. The pressure in each of the load-lock chambers 41a and 41b can be changed between the predetermined vacuum level and the atmospheric pressure (or close to the atmospheric pressure), so that the environment around the wafer W can be equivalent to that inside the transfer chamber 31. The load-lock chambers 41a and 41b are connected to the transfer chamber 31 through gate valves G5 and G6 and also connected to the loader unit 21 through gate valves G7 and G8, respectively.

Besides, each of the load-lock chambers 41a and 41b can accommodate therein a plurality of wafers W. In order to accommodate a plurality of wafers W, each of the load-lock chambers 41 (41a and 41b) can have a structure in which a number of wafers W are arranged on top of one another at different heights. In this example, two wafers W are arranged on top of one another respectively at an upper and a lower stage.

A loading/unloading device 24 is provided inside the loader unit 21. The loading/unloading device 24 performs loading and unloading of the wafers W as well as transferring them between the carrier C and the loader unit 21, between the loader unit 21 and the orienter 23, and between the loader unit 21 and the load-lock chambers 41a and 41b. The loading/unloading device 24 is configured to have a plurality of multi-joint arms 25 and travel on a rail 26 extending along the longer side direction of the loader unit 21. In this example, two multi-joint arms 25a and 25b are provided. The multi-joint arms 25a and 25b have picks 27a and 27b at leading ends thereof. In order to load a wafer W into the processing unit 3, the wafer W is unloaded from a carrier C by using the pick 27a or 27b and then is loaded into the orienter 23. Next, the direction of the wafer W is adjusted in the orienter 23. Thereafter, the wafer W is unloaded from the orienter 23 by using the pick 27a or 27b and then is loaded into the load-lock chamber 41a or 41b. When the wafer W is ready to be unloaded from the processing unit 3, the wafer W is unloaded from the load-lock chamber 41a or 41b by using the pick 27a or 27b and then is loaded into the carrier C.

A transfer device 33 in accordance with the first embodiment of the present invention is provided inside the transfer chamber 31. The transfer device 33 performs loading and unloading of the wafers W as well as transferring them between the load-lock chambers 41a and 41b and the transfer chamber 31 and between the transfer chamber 31 and the processing chambers 32a to 32d. In this example, the transfer device 33 is disposed substantially at the center of the transfer chamber 31.

The control unit 5 has a process controller 51, a user interface 52, and a storage unit 53. The process controller 51 has a microprocessor (computer). The user interface 52 has a keyboard through which an operator inputs commands to manage the semiconductor manufacturing apparatus 1a, a display for visually displaying an operation status of the semiconductor manufacturing apparatus 1a or the like. The storage unit 53 stores therein control programs for implementing various processes performed by the semiconductor manufacturing apparatus 1a under the control of the process controller 51 and recipes for executing processes in the semiconductor manufacturing apparatus 1a in accordance with various data and process conditions. The recipes are stored in a storage medium of the storage unit 53. The storage medium may be a computer readable storage medium, e.g., a hard disk, or a portable storage medium such as a CD-ROM, a DVD, a flash memory or the like. Alternatively, the recipes may be appropriately transmitted from another device via, e.g., a dedicated transmission line. A certain recipe is retrieved from the storage unit 53 under an instruction inputted through the user interface 52 and executed by the process controller 51, so that a desired process is performed in the semiconductor manufacturing apparatus 1a under the control of the process controller 51.

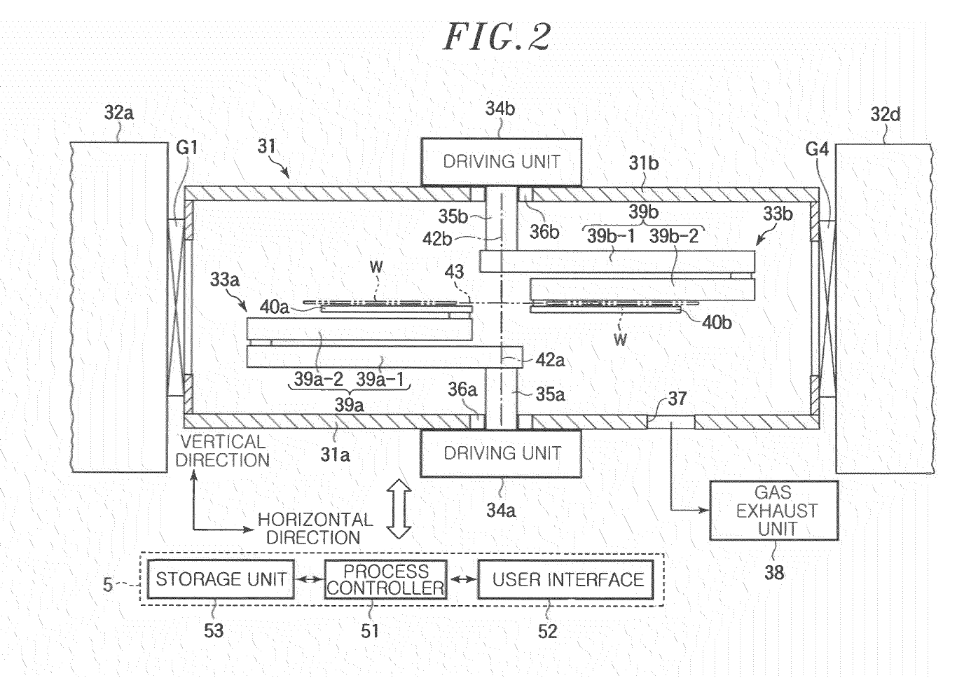

FIG. 2 is a cross sectional view schematically showing an example of the transfer device in accordance with the first embodiment of the present invention. Further, FIG. 2 is a cross sectional view taken along line II-II shown in FIG. 1.

As shown in FIG. 2, the transfer device 33 in accordance with the first embodiment includes a lower transfer mechanism 33a and an upper transfer mechanism 33b vertically arranged at a lower and an upper stage, respectively.

The lower transfer mechanism 33a is provided substantially at a central area of a bottom plate 31a of the transfer chamber 31. In this example, a driving unit 34a for driving the lower transfer mechanism 33a is installed outside the bottom plate 31a. A shaft 35a rotated by the driving unit 34a is arranged vertically toward the inside of the transfer chamber 31 through the bottom plate 31a. A seal portion 36a is disposed between the shaft 35a and the bottom plate 31a to airtightly seal the inside of the transfer chamber 31 from the outside having the atmospheric pressure. A gas exhaust port 37 is provided at, e.g., the bottom plate 31a of the transfer chamber 31, and is connected to a gas exhaust unit 38. The gas exhaust unit 38 reduces the pressure inside the transfer chamber 31 to the same level as that inside the processing chambers 32a to 32d.

A horizontally extensible and retractable arm 39a is attached to the shaft 35a. The arm 39a has at a leading end thereof a pick 40a for holding the wafer W. The arm 39a and the pick 40a are rotated by the rotation of the shaft 35a.

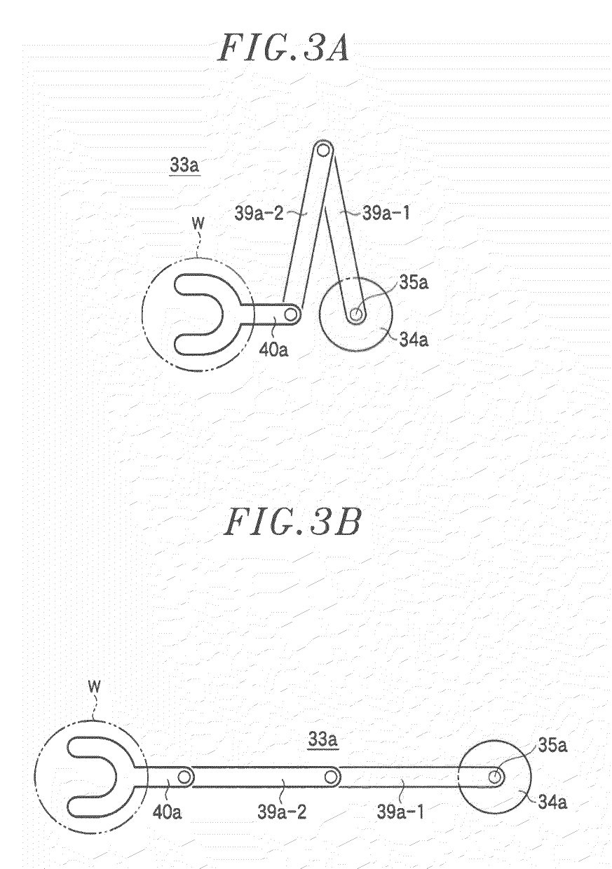

In this example, the arm 39a includes a first arm 39a-1 and a second arm 39a-2 arranged in that order from the shaft 35a, and the pick 40a is attached to a leading end of the second arm 39a-2. The first arm 39a-1, the second arm 39a-2 and the pick 40a are installed in that order from the bottom plate 31a. The arm retracted state indicates a state in which the first arm 39a-1 and the second arm 39a-2 are folded as shown in FIG. 3A. The rotation of the shaft 35a is carried out, e.g., in the arm retracted state. Further, the arm extended state indicates a state in which the first arm 39a-1 and the second arm 39a-2 are stretched as shown in FIG. 3B. The operations of transferring wafers W in the processing chambers 32a to 32d and in the load-lock chambers 41a and 41b are carried out in, e.g., the arm extended state.

As described above, the lower transfer mechanism 33a is configured as a two-axes driving transfer apparatus, wherein a driving axis for the rotation of the shaft 35a is referred to as a θ1 axis, and another driving axis for the extension and retraction of the arm 39a is referred to as a θ2 axis.

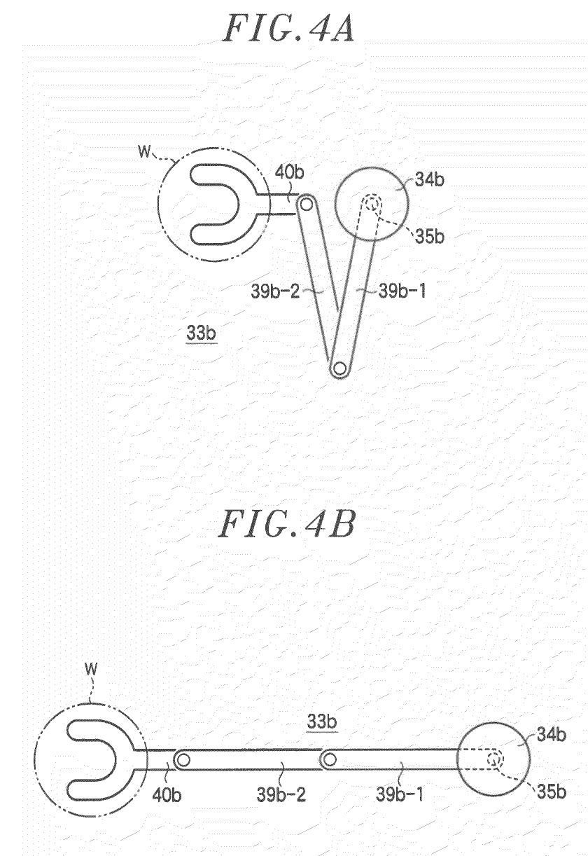

The upper transfer mechanism 33b is disposed substantially at a central area of a top plate 31b of the transfer chamber 31. The upper transfer mechanism 33b has substantially the same configuration as that of the lower transfer mechanism 33a. Therefore, like reference numerals will be given to like parts except that the letter suffix “a” in the reference numerals will be substituted by the suffix “b”, and the description thereof will be omitted. However, the upper transfer mechanism 33b is different from the lower transfer mechanism 33a in that a first arm 39b-1, a second arm 39b-2 and a pick 40b are installed in the opposite order, that is, the upper transfer mechanism 33b includes the pick 40b, the second arm 39b-2 and the first arm 39b-1 installed in that order from the bottom plate 31a. The arm retracted state and the arm extended state of the upper transfer mechanism 33b are shown in FIGS. 4A and 4B, respectively.

In this example, the upper transfer mechanism 33b and the lower transfer mechanism 33a are vertically separated from each other while a rotation center (i.e., axis) 42b of the shaft 35b arranged vertically coincides with a rotation center 42a of the shaft 35a arranged vertically.

Moreover, the vertical position of the pick 40b of the upper transfer mechanism 33b is set such that the wafer W held by the pick 40b and the wafer W held by the pick 40a are disposed at a same height. Accordingly, the wafer W held by the pick 40a and the wafer W held by the pick 40b are moved on a same horizontal plane 43 in the transfer chamber 31.

In the transfer device 33 in accordance with the first embodiment of the present invention, the arm 39a and the pick 40a of the lower transfer mechanism 33a and the arm 39b and the pick 40b of the upper transfer mechanism 33b can be rotated up to 360 degrees or more about the θ1 axis of the lower transfer mechanism 33a (hereinafter, referred to as a “θ1a axis”) and about the θ1 axis of the upper transfer mechanism 33b (hereinafter, referred to as a “θ1b axis”), respectively.

Accordingly, it is possible to arbitrarily adjust the angle between the picks 40a and 40b and the directions of the picks 40a and 40b, as will be described hereinafter.

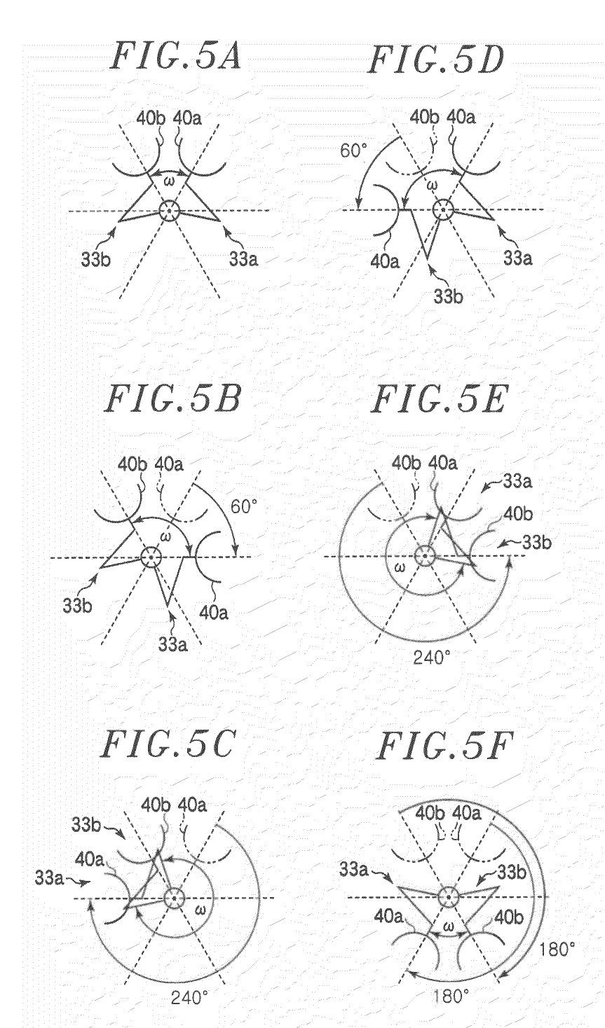

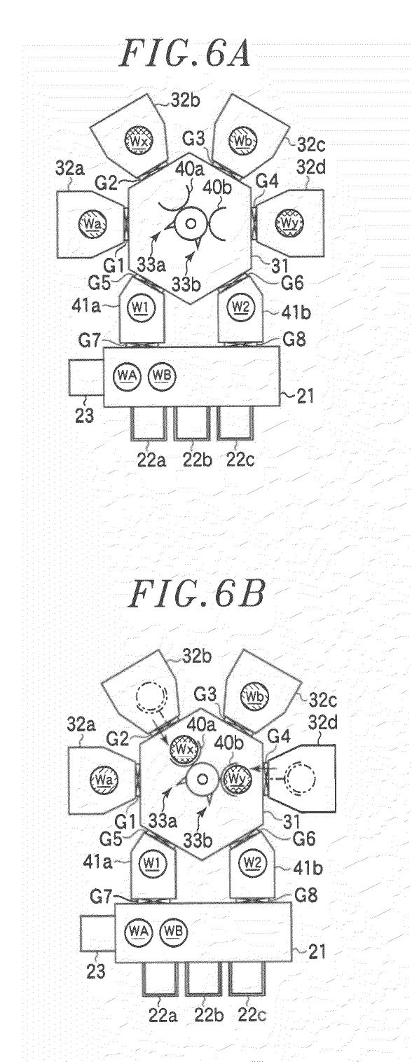

FIGS. 5A to 5F are top views schematically showing examples of adjusting the angle between the picks 40a and 40b and the directions of the picks 40a and 40b.

FIG. 5A shows an example in which the angle ω between the picks 40a and 40b is 60 degrees, and this will be referred to as an initial state in this example. The examples of adjusting the angle between the picks 40a and 40b will be described from the above initial state.

FIG. 5B shows an example in which the pick 40a is rotated by 60 degrees from the initial state shown in FIG. 5A in a clockwise direction by rotating the θ1a axis of the lower transfer mechanism 33a. In this case, the angle ω between the picks 40a and 40b becomes 120 degrees.

FIG. 5C shows an example in which the pick 40a is rotated by 240 degrees from the initial state in the clockwise direction by rotating the θ1a axis of the lower transfer mechanism 33a. In this case, the angle u between the picks 40a and 40b becomes 300 degrees.

FIG. 5D shows an example in which the pick 40b is rotated by 60 degrees from the initial state in a counterclockwise direction by rotating the θ1b axis of the upper transfer mechanism 33b. In this case, the angle ω between the picks 40a and 40b becomes 120 degrees.

FIG. 5E shows an example in which the pick 40b is rotated by 240 degrees from the initial state in the counterclockwise direction by rotating the θ1b axis of the upper transfer mechanism 33b. In this case, the angle ω between the picks 40a and 40b becomes 300 degrees.

FIG. 5F shows an example in which the picks 40a and 40b are rotated simultaneously by 180 degrees from the initial state in the clockwise direction by rotating both of the θ1a axis of the lower transfer mechanism 33a and the θ1b axis of the upper transfer mechanism 33b. In this case, the directions of the picks 40a and 40b are changed by rotating the picks 41a and 41b 180 degrees from the initial state shown in FIG. 5A while maintaining the angle u between the pick 40a and the pick 40b at 60 degrees.

As described above, the transfer device 33 in accordance with the first embodiment is advantageous in that it is possible to arbitrarily adjust the angle between the picks 40a and 40b and the directions of the picks 40a and 40b.

In comparison with the conventional transfer device having a configuration in which each transfer mechanism needs to have three or four driving axes to perform operations including, e.g., arm extension and retraction of the transfer device and height adjustment of each pick, the transfer device 33 in accordance with the first embodiment includes vertically and separately installed transfer mechanisms, i.e., the lower and the upper transfer mechanism 33a and 33b, each having two driving axes to perform such operations including, e.g., arm extension and retraction of the transfer device 33 as shown in FIGS. 5A to 5F.

Therefore, the transfer device 33 constituted by two transfer mechanisms 33a and 33b each being the two-axes driving transfer apparatus, is of a simple structure or mechanism compared to the conventional case, wherein each transfer mechanism is the three-axes or four-axes driving transfer apparatus.

By simplifying the structure or the mechanism of the transfer device, the cost of the transfer device can be reduced, and the maintenance can be easily performed. In addition, troubles such as breakdown and the like can be reduced compared to the case where the transfer device has a complicated structure or mechanism.

Further, in accordance with the transfer device 33 of the first embodiment, the angle between the picks 40a and 40b and the directions of the picks 40a and 40b can be arbitrarily adjusted and, hence, the following transfer method can be performed.

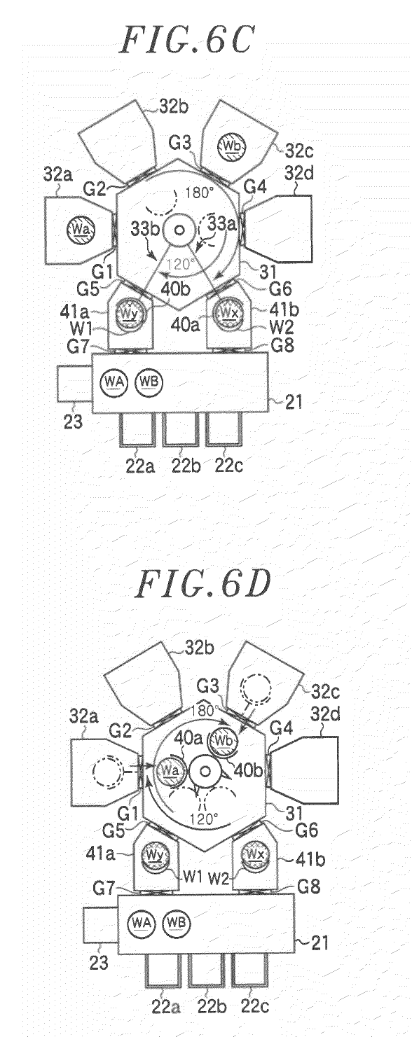

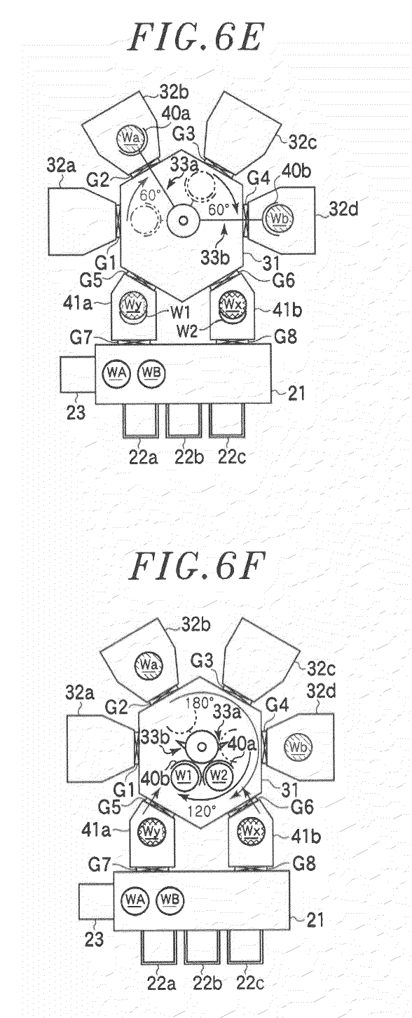

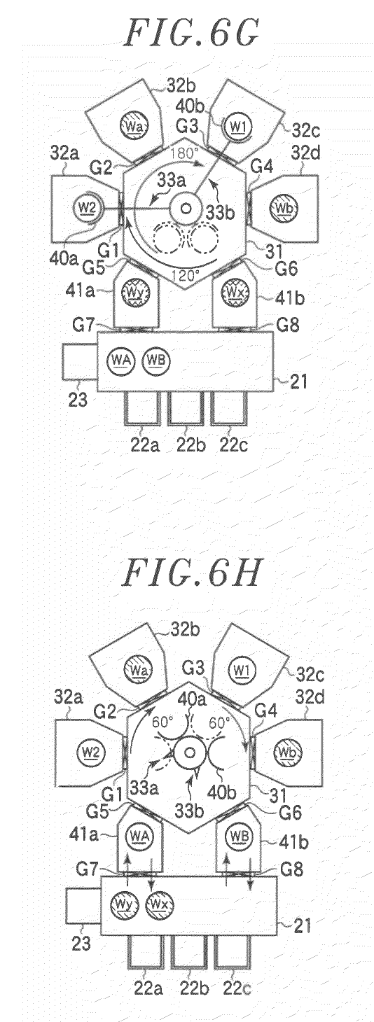

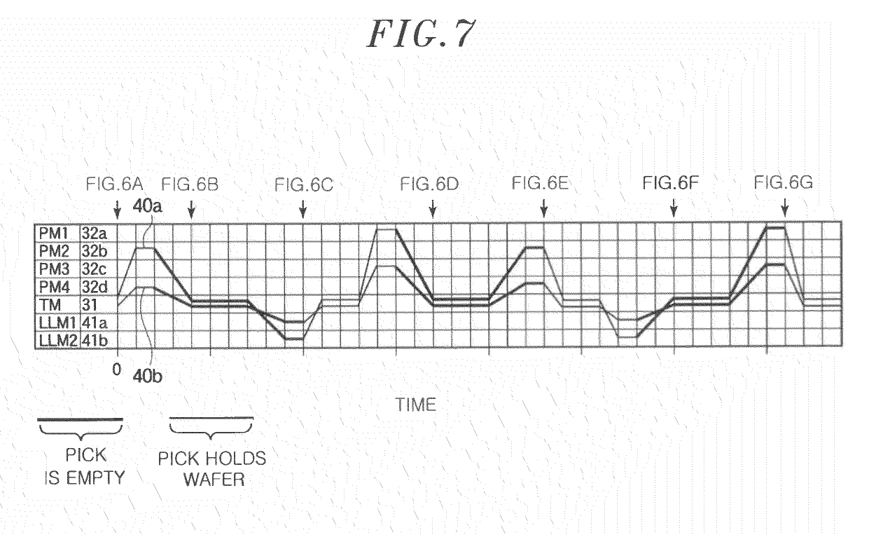

FIGS. 6A to 6H are top views, each showing an example of the target object transfer method that can be performed by the transfer device in accordance with the first embodiment of the present invention. FIG. 7 is a timing diagram thereof.

In this example, a first wafer processing is performed in the processing chambers 32a and 32c, and then a subsequent processing that is different from the first processing is performed in the processing chambers 32b and 32d.

First, as shown in FIGS. 6A and 7, wafers to be processed W1 and W2 are loaded into the load-lock chambers 41a and 41b, respectively. At this time, the angle between the picks 40a and 40b is set to 120 degrees such that the pick 40a of the lower transfer mechanism 33a is positioned in front of the gate valve G2 to thereby communicate with the processing chamber 32b and the pick 40b of the upper transfer mechanism 33b is positioned in front of the gate valve G4 to thereby communicate with the processing chamber 32d.

In the processing chambers 32a and 32c, the processing of each of the wafers Wa and Wb is completed. In the processing chambers 32b and 32d, the processing of each of the wafers Wx and Wy is completed.

Next, as shown in FIGS. 6B and 7, the processed wafers Wx and Wy are simultaneously unloaded from the processing chambers 32b and 32d and loaded into the transfer chamber 31 by moving the lower transfer mechanism 33a and the upper transfer mechanism 33b, respectively.

Thereafter, as shown in FIGS. 6C and 7, the pick 40a is rotated by 180 degrees in the clockwise direction by rotating the θ1a axis of the lower transfer mechanism 33a. At the same time, the pick 40b is rotated by 120 degrees in the clockwise direction by rotating the θ1b axis of the upper transfer mechanism 33b. As a consequence, the pick 40a is positioned in front of the gate valve G6 to thereby communicate with the load-lock chamber 41b, and the pick 40b is positioned in front of the gate valve G5 to thereby communicate with the load-lock chamber 41a. Moreover, the angle between the picks is reduced from 120 degrees to 60 degrees. Then, the processed wafers Wy and Wx are simultaneously loaded from the transfer chamber 31 into the load-lock chambers 41a and 41b by moving the upper transfer mechanism 33b and the lower transfer mechanism 33a, respectively. As illustrated, the processed wafers Wy and Wx are positioned above or below the wafers to be processed W1 and W2 in the load-lock chambers 41a and 41b, respectively.

Next, as shown in FIGS. 6D and 7, the pick 40b is rotated by 180 degrees in the clockwise direction by rotating the θ1b axis of the upper transfer mechanism 33b. At the same time, the pick 40a is rotated by 120 degrees in the clockwise direction by rotating the θ1a axis of the lower transfer mechanism 33a. As a consequence, the pick 40b is positioned in front of the gate valve G3 to thereby communicate with the processing chamber 32c, and the pick 40a is positioned in front of the gate valve G1 to thereby communicate with the processing chamber 32a. Furthermore, the angle between the picks is increased from 60 degrees to 120 degrees. Thereafter, the processed wafers Wa and Wb are simultaneously unloaded from the processing chambers 32a and 32c and loaded into the transfer chamber 31 by moving the lower transfer mechanism 33a and the upper transfer mechanism 33b, respectively.

Then, as shown in FIGS. 6E and 7, the pick 40b is rotated by 60 degrees in the clockwise direction by rotating the θ1b axis of the upper transfer mechanism 33b. At the same time, the pick 40a is rotated by 60 degrees in the clockwise direction by rotating the θ1a axis of the lower transfer mechanism 33a. As a consequence, the pick 40b is positioned in front of the gate valve G4 to thereby communicate with the processing chamber 32d, and the pick 40a is positioned in front of the gate valve G2 to thereby communicate with the processing chamber 32b. Further, the angle between the picks is maintained at 120 degrees. Next, the processed wafers Wa and Wb are simultaneously loaded into the processing chambers 32b and 32d from the transfer chamber 31 by moving the lower transfer mechanism 33a and the upper transfer mechanism 33b, respectively.

Thereafter, as shown in FIGS. 6F and 7, the pick 40a is rotated by 180 degrees in the clockwise direction by rotating the θ1a axis of the lower transfer mechanism 33a.

At the same time, the pick 40b is rotated by 120 degrees in the clockwise direction by rotating the θ1b axis of the upper transfer mechanism 33b. As a consequence, the pick 40a is positioned in front of the gate valve G6 to thereby communicate with the load-lock chamber 41b, and the pick 40b is positioned in front of the gate valve G5 to thereby communicate with the load-lock chamber 41a. The angle between the picks is reduced from 120 degrees to 60 degrees. Then, the wafers to be processed W1 and W2 are simultaneously loaded from the load-lock chambers 41a and 41b into the transfer chamber 31 by moving the upper transfer mechanism 33b and the lower transfer mechanism 33a, respectively.

Next, as shown in FIGS. 6G and 7, the pick 40b is rotated by 180 degrees in the clockwise direction by rotating the θ1b axis of the upper transfer mechanism 33b. At the same time, the pick 40a is rotated by 120 degrees in the clockwise direction by rotating the θ1a axis of the lower transfer mechanism 33a. As a consequence, the pick 40b is positioned in front of the gate valve G3 to thereby communicate with the processing chamber 32c, and the pick 40a is positioned in front of the gate valve G1 to thereby communicate with the processing chamber 32a. The angle between the picks is increased from 60 degrees to 120 degrees. Thereafter, the wafers to be processed W2 and W1 are simultaneously loaded from the transfer chamber 31 into the processing chambers 32a and 32c by moving the lower transfer mechanism 33a and the upper transfer mechanism 33b, respectively.

Then, as shown in FIGS. 6H and 7, the processed wafers Wy and Wx are unloaded from the load-lock chambers 41a and 41b. Next, the wafers to be processed WA and WB are loaded into the load-lock chambers 41a and 41b, respectively. In the meantime, the pick 40b is rotated by 60 degrees in the clockwise direction by rotating the θ1b axis of the upper transfer mechanism 33b, and the pick 40a is rotated by 60 degrees in the clockwise direction by rotating the θ1a axis of the lower transfer mechanism 33a. As a consequence, the pick 40b is positioned in front of the gate valve G4 to thereby communicate with the processing chamber 32d, and the pick 40a is positioned in front of the gate valve G2 to thereby communicate with the processing chamber 32b. In other words, the process shown in FIG. 6H is a step returning to the process shown in FIG. 6A.

Although it is not illustrated, the processed wafers Wa and Wb are simultaneously unloaded into the transfer chamber 31 from the processing chambers 32b and 32d and then loaded into the load-lock chambers 41b and 41a from the transfer chamber 31, respectively, in the same sequence shown in FIGS. 6A to 6H.

Next, the processed wafers W2 and W1 are simultaneously unloaded into the transfer chamber 31 from the processing chambers 32a and 32c and then loaded into the processing chambers 32b and 32d from the transfer chamber 31, respectively.

Thereafter, the wafers to be processed WA and WB are simultaneously loaded from the load-lock chambers 41a and 41b into the transfer chamber 31 and then loaded from the transfer chamber 31 into the processing chambers 32c and 32a.

By repeating the processes shown in FIGS. 6A to 6H, a plurality of processed wafers can be transferred to a next processing, and a plurality of completely processed wafers can be exchanged with a plurality of wafers to be processed.

In accordance with the target object transfer method described above, a plurality of, e.g., two in this example, wafers to be processed and processed wafers are loaded and unloaded simultaneously. Therefore, the loading and unloading operation can be performed in a shorter period of time compared to a transfer method in which wafers are loaded and unloaded one at a time, and it is possible to solve the problem in which the increase in the productivity is limited even if the processing time in the processing apparatus is reduced.

Such transfer method can be performed by the transfer device 33 in accordance with the first embodiment of the present invention.

Overall, in accordance with the transfer device 33 of the first embodiment, it is possible to obtain the transfer device having a simple structure and capable of solving the problem in which the increase in the productivity is limited even if the processing time in the processing apparatus is reduced, and the target object processing apparatus including the transfer device.

### Second Embodiment

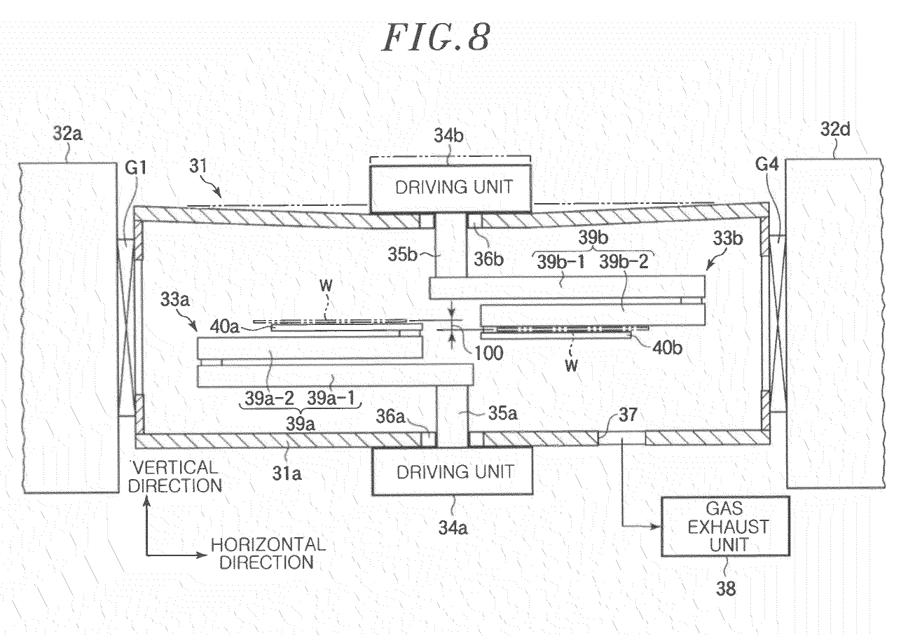

FIG. 8 is a cross sectional view for explaining a state in which the upper transfer mechanism 33b of the transfer device is attached to the top plate 31b.

As shown in FIG. 8, when the upper transfer mechanism 33b is attached to the top plate 31b, the top plate 31b may be bent due to the weight of the upper transfer mechanism 33b.

Further, when the pressure inside the transfer chamber 31 is lower than an outside pressure, e.g., the atmospheric pressure, the top plate 31b may be bent by being pressed by the atmospheric pressure.

When the top plate 31b is bent, the position of the wafer W held by the pick 40a and that of the wafer W held by the pick 40b are misaligned in the vertical direction as indicated by a reference numeral 100 in FIG. 8, which may decrease the transfer accuracy.

In order to suppress such bending of the top plate 31b, it is required to increase the stiffness of the top plate 31b. When the stiffness of the top plate 31b is increased enough, it becomes possible to suppress the misalignment between the position of the wafer W held by the pick 40a and that of the wafer W held by the pick 40b.

On the other hand, when the stiffness of the top plate 31b is increased, the top plate 31b may become heavy, which makes it difficult to separate the top plate 31 for the maintenance operation. Besides, the manufacturing cost of the top plate 31b may be increased.

In the second embodiment of the present invention, there is provided a transfer device capable of suppressing the misalignment between positions of the wafers W while the easily separable top plate 31b is provided and the manufacturing cost thereof is reduced and a target object processing apparatus including the transfer device.

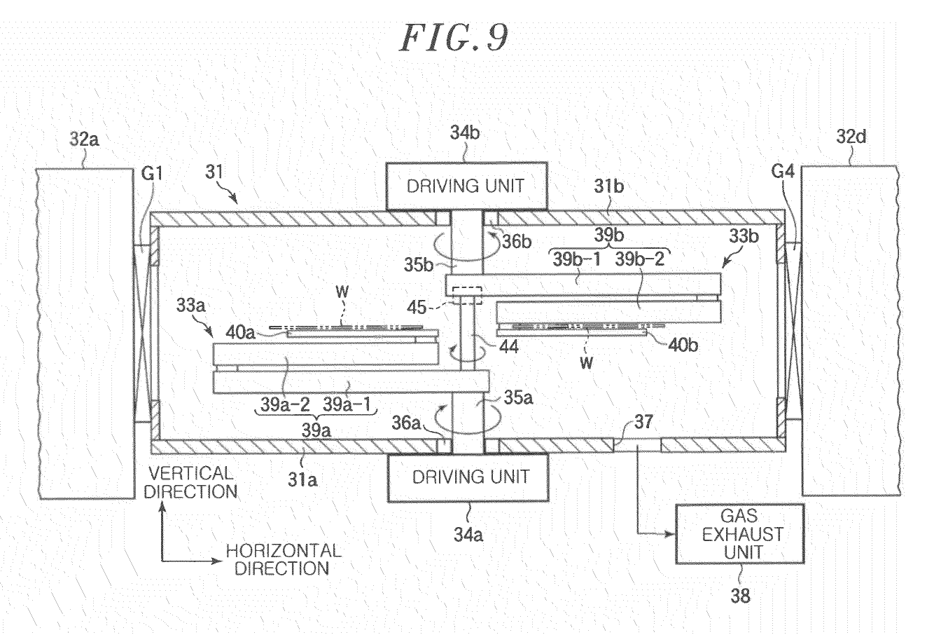

FIG. 9 is a cross sectional view schematically showing an example of the transfer device in accordance with the second embodiment of the present invention.

As shown in FIG. 9, the transfer device of the second embodiment is different from that of the first embodiment in that a column 44 is provided between the shaft 35a of the lower transfer mechanism 33a and the shaft 35b of the upper transfer mechanism 33b. The other configurations of the transfer device of the second embodiment are the same as those of the transfer device of the first embodiment.

By providing the column 44 between the shafts 35a and 35b, the upper transfer mechanism 33b is supported by the column 44. Hence, even if the top plate 31b is pressed by the weight of the upper transfer mechanism 33b or by the outside pressure, e.g., the atmospheric pressure, the vertical distance between the upper transfer mechanism 33b and the lower transfer mechanism 33a can be constantly maintained by the column 44.

As described above, in accordance with the transfer device of the second embodiment, the vertical distance between the upper transfer mechanism 33b and the lower transfer mechanism 33a can be constantly maintained by the column 44, so that it is possible to suppress the misalignment between the vertical position of the wafer W held by the pick 40a and that of the wafer W held by the pick 40b.

Further, it is unnecessary to increase the stiffness of the top plate 31b. For example, the compactness of the top plate 31b can be obtained.

Overall, in accordance with the second embodiment, it is possible to obtain the transfer device capable of suppressing the misalignment between the vertical positions of the wafers W while easily separable top plate 31b is also provided and the manufacturing cost thereof is reduced and the target object processing apparatus including the transfer device.

Further, for example, if the column 44 is fixed to, e.g., the shaft 35a of the lower transfer mechanism 33a, the column 44 is rotated in accordance with the rotation of the shaft 35a. At this time, the shaft 35b of the upper transfer mechanism 33b either, e.g., stops rotating or is rotated in the opposite direction to the rotation direction of the shaft 35a, regardless of the rotation of the shaft 35a. Thus, it is preferable to bring the column 44 into contact with the shaft 35b without fixing the column 44 to the shaft 35b of the upper transfer mechanism 33b. The contact surface between the column 44 and the shaft 35b serves as a sliding surface where the column 44 and the shaft 35b slide against each other. The contact surface itself may serve simply as the sliding surface; however, if the friction between the column 44 and the shaft 35b needs to be reduced, a sliding mechanism 45 for allowing the sliding movement between the column 44 and the shaft 35b may be provided on the contact surface between the column 44 and the shaft 35b. Further, the column 44 may be fixed to the upper transfer mechanism 33b. In this case, the sliding mechanism 45 may be provided on a contact surface between the column 44 and the shaft 35a.

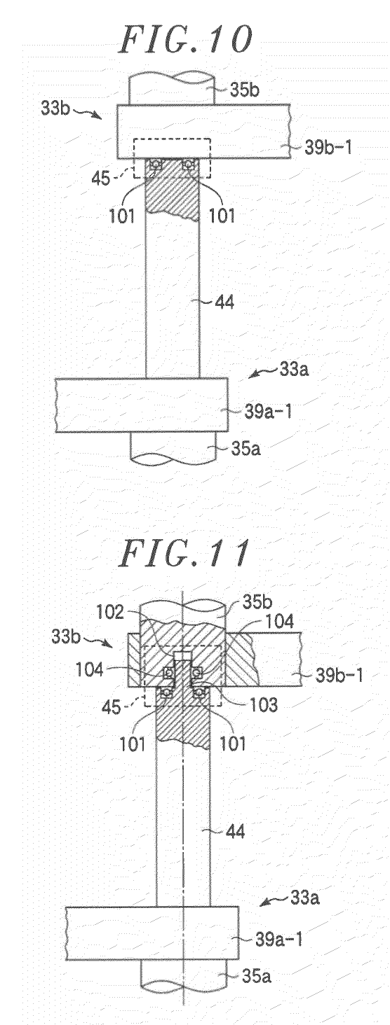

FIG. 10 is a side view showing a fragmentary cross section of an example of the sliding mechanism.

As shown in FIG. 10, in the sliding mechanism 45 of this example, a bearing 101 is attached to a leading end of the column 44. Due to the rolling of the bearing 101, the column 44 and the shaft 35b can slide against each other with reduced friction. Although the bearing 101 is attached to the leading end of the column 44 in this example, the bearing 101 may be attached to the shaft 35b. That is, the sliding mechanism 45 is preferably provided on the contact surface between the column 44 and the shaft 35b.

Further, the column 44 can serve as a positioning member for making the rotation center of the shaft 35a of the lower transfer mechanism 33a coincide with the rotation center of the shaft 35b of the upper transfer mechanism 33b.

FIG. 11 is a side view showing a fragmentary cross section of an example in which the column is used as the positioning member.

As shown in FIG. 11, when the column 44 is used as the positioning member, a positioning hole 102 to which the column 44 can be insertion-fitted is formed, e.g., at the central axis of the shaft 35b of the upper transfer mechanism 33b. Preferably, the entire leading end of the column 44 or a protrusion 103 formed at the leading end of the column 44 is insertion-fitted to the positioning hole 102. In this case, a side surface of the positioning hole 102 serves as a sliding surface where the column 44 or the protrusion 103 slides thereon. Further, a sliding mechanism 104 may be provided, e.g., at the side surface of the positioning hole 102. In this example, the bearing is used as an example of the sliding mechanism 104. Moreover, the sliding mechanism 104 is not necessarily provided at the side surface of the positioning hole 102, i.e., at the shaft 35b, and may be provided at a side surface of the leading end of the column 44 or a side surface of the protrusion 103. Similarly, in case where the column 44 is fixed to the upper transfer mechanism 33b, the positioning hole 102 may be formed, e.g., at the central axis of the shaft 35a of the lower transfer mechanism 33a.

In addition, the column 44 can be used as a distance adjustment member for adjusting a vertical distance between the lower transfer mechanism 33a and the upper transfer mechanism 33b.

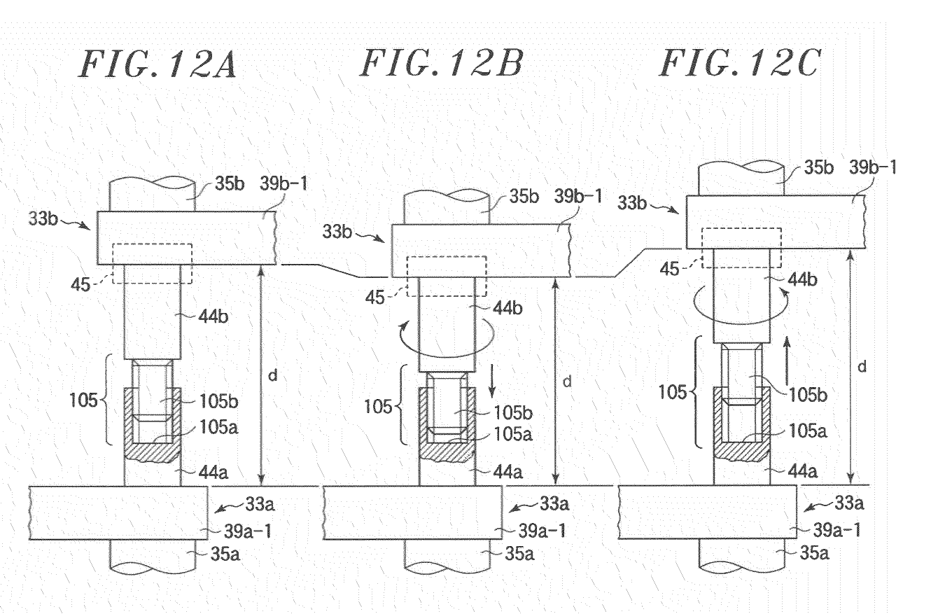

FIGS. 12A to 12C are side views showing fragmentary cross sections of an example in which the column is used as the distance adjustment member.

As shown in FIG. 12A, when the column 44 is used as the distance adjustment member, it is preferable to provide at the column 44 a length adjustment unit 105 for adjusting a length of the column 44. In this example, the length adjustment unit 105 having a screw mechanism is provided, and the column 44 is divided into, e.g., a lower column 44a and an upper column 44b. A recess 105a having a screw thread at the side surface thereof is formed at a leading end of the lower column 44a, and a protrusion 105b having a screw thread at a side surface thereof is formed at a leading end of the upper column 44b. The protrusion 105b is inserted into the recess 105a.

In this example, when the upper column 44b is rotated in the clockwise direction, the protrusion 105b is further advanced into the recess 105a, so that the vertical distance d between the lower transfer mechanism 33a and the upper transfer mechanism 33b can be reduced.

On the contrary, when the upper column 44b is rotated in the counterclockwise direction, the protrusion 105b is further receded in the recess 105a to be raised as shown in FIG. 12C. Hence, the vertical distance d between the lower transfer mechanism 33a and the upper transfer mechanism 33b can be increased.

As described above, the vertical distance d between the lower transfer mechanism 33a and the upper transfer mechanism 33b can be adjusted by providing to the column 44 the length adjustment unit 105 for adjusting the length of the column 44.

Preferably, the vertical distance d between the lower transfer mechanism 33a and the upper transfer mechanism 33b is adjusted after the lower transfer mechanism 33a and the upper transfer mechanism 33b are respectively installed at the bottom plate 31a and the top plate 31b, i.e., after the transfer device 33 is installed at the transfer chamber 31, to thereby reduce the installation error.

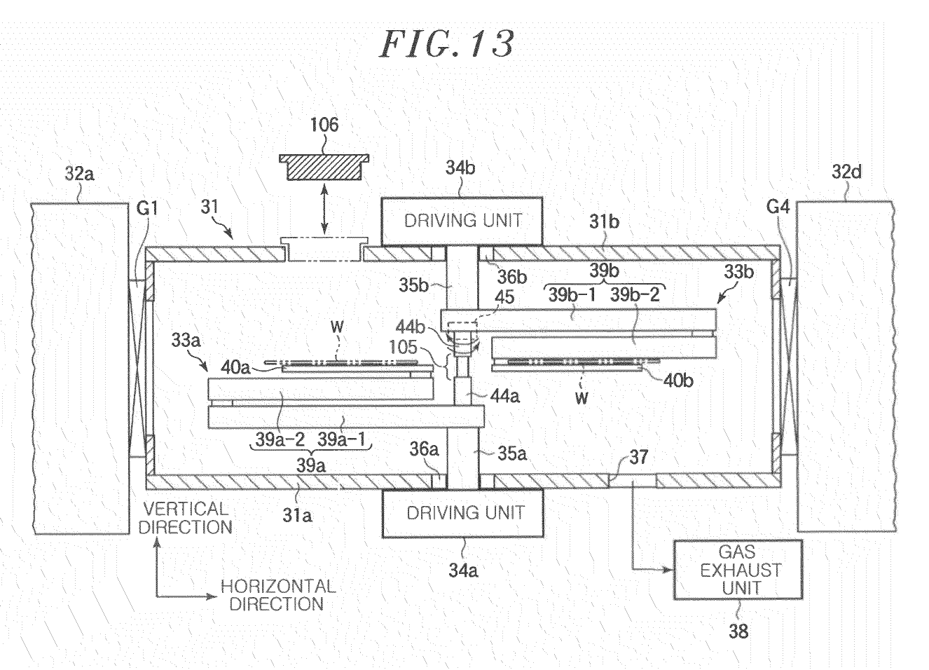

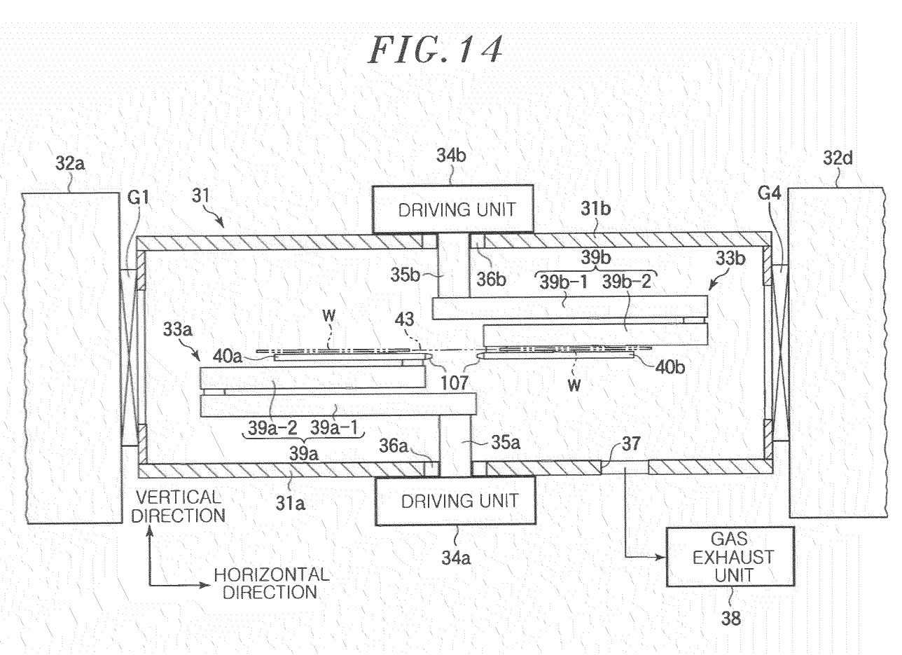

After the transfer device 33 is installed in the transfer chamber 31, an openable/closable window 106 may be provided at the top plate 31b of the transfer chamber 31 as shown in FIG. 13, for example, in order to easily adjust the vertical distance d between the lower transfer mechanism 33a and the upper transfer mechanism 33b.

### Third Embodiment

In the transfer device 33 in accordance with the first and the second embodiment of the present invention, the pick 40a of the lower transfer mechanism 33a and the pick 40b of the upper transfer mechanism 33b can be rotated up to 360 degrees or more. Accordingly, if the power supply is stopped by a power failure or the like during the rotation of the pick 40a or 40b, the pick 40a or 40b may continue rotating due to the inertia.

The wafer W held by the pick 40a and the wafer W held by the pick 40b are moved on the same horizontal plane 43. Thus, if the pick 40a or 40b continues rotating due to the inertia, the wafers W may collide with each other to be damaged.

The third embodiment of the present invention provides a transfer device capable of preventing collision between wafers W and a target object processing apparatus including the transfer device.

FIG. 14 is a cross sectional view schematically showing an example of the transfer device in accordance with the third embodiment of the present invention.

As shown in FIG. 14, the transfer device of the third embodiment is different from that of the first embodiment in that the picks 40a and 40b are provided with collision preventing members 107 for preventing collision between the wafer W held by the pick 40a and the wafer W held by the pick 40b. Other configurations of the transfer device of the third embodiment are the same as those of the transfer device of the first embodiment.

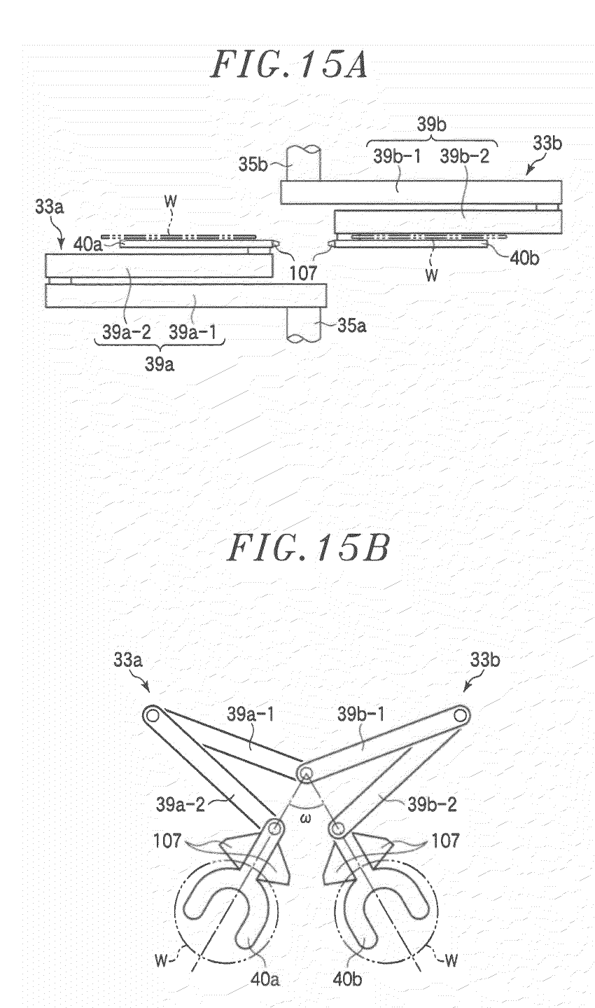

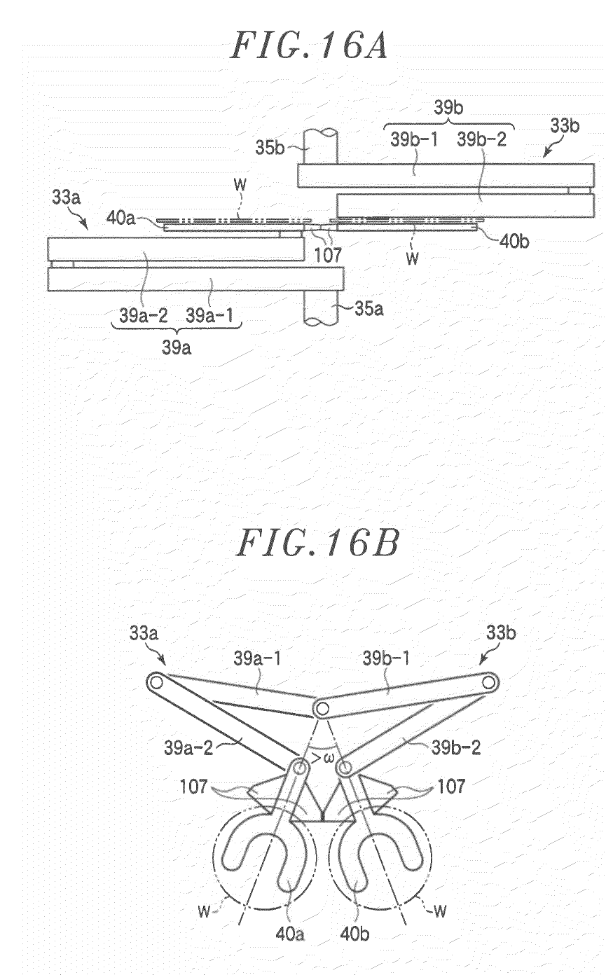

FIG. 15A is a side view in a normal state, and FIG. 15B is a top view in the normal state. FIG. 16A is a side view in a power failure state, and FIG. 16B is a top view in the power failure state.

As shown in FIGS. 15A and 15B, in the normal state, the angle co between the picks is limited by, e.g., a control program, to thereby prevent the collision between the wafer W held by the pick 40a and the wafer W held by the pick 40b.

However, in the power failure state, the pick 40a or 40b may continue to be rotated due to the inertia as shown in FIGS. 16A and 16B and, thus, the angle u between the picks may become smaller than a limited angle therebetween. To that end, the collision preventing members 107 protruding horizontally are provided at both side surfaces of the pick 40a and both side surfaces of the pick 40b. The collision preventing members 107 collide with each other before the wafers W can collide with each other, so that the angle between the picks 40a and 40b does not become smaller than the limited angle therebetween. Accordingly, the collision between the wafers W can be avoided, which resultantly prevents undesired damages of the wafers W.

In this example, the collision preventing members 107 are provided at respective both sides of the picks 40a and 40b, so that the wafers W can be prevented from colliding with each other due to the rotation due to the inertia either the clockwise or the counterclockwise direction.

As described above, in accordance with the third embodiment, it is possible to obtain the transfer device capable of preventing the collision between the wafers W and the target object processing apparatus including the transfer device.

Further, the third embodiment can be implemented in combination with the second embodiment.

The present invention may be variously modified without being limited to the above-described embodiment.

For example, although two arms 39a and 39b are provided in the above-described embodiments, three or more arms can be provided.

Further, although the column 44 is fixed to either the lower transfer mechanism 33a or the upper transfer mechanism 33b in the above-described embodiments, the column 44 may be brought into contact with both of the shafts 35a and 35b without fixing the column 44 to any one of the shafts 35a and 35b. In this case, the sliding mechanism 45 may be provided on both of the contact surfaces between the column 44 and the shafts 35a and 35b. Similarly, the positioning hole 102 may be formed, e.g., at each of the central axes of the shafts 35a and 35b.

In accordance with the embodiments of the present invention, it is possible to provide a transfer device and a target object processing apparatus including the transfer device having a simple structure and capable of solving the problem in which the increase in the productivity is limited even if the processing time in the processing apparatus is reduced.

While the invention has been shown and described with respect to the embodiments, it will be understood by those skilled in the art that various changes and modifications may be made without departing from the scope of the invention as defined in the following claims.

What is claimed is:

1. A transfer device comprising:
a first transfer mechanism including a first shaft which is rotatable and vertically arranged and a horizontally extensible and retractable first arm having at a leading end thereof a first pick for holding a processing target object, the first arm being attached to the first shaft;
a second transfer mechanism including a second shaft which is rotatable and vertically arranged and a horizontally extensible and retractable second arm having at a leading end thereof a second pick for holding a processing target object, the second arm being attached to the second shaft,
wherein the first and the second transfer mechanism are vertically separated from each other while a rotation center of the first shaft and that of the second shaft coincide with each other.

2. The transfer device of claim 1, wherein vertical positions of the first pick and the second pick are set such that the target object held by the first pick and the target object held by the second pick move on a same horizontal plane.

3. The transfer device of claim 1, wherein the first and the second transfer mechanism are respectively provided at a ceiling portion and a bottom portion of a transfer chamber in which the transfer device is accommodated.

4. The transfer device of claim 3, wherein the first transfer mechanism is provided at a substantially central area of the ceiling portion of the transfer chamber, and the second transfer mechanism is provided at a substantially central area of the bottom portion of the transfer chamber.

5. The transfer device of claim 1, further comprising a column provided between the first shaft and the second shaft.

6. The transfer device of claim 5, wherein a sliding mechanism is provided on a contact surface between the column and the first or the second shaft.

7. The transfer device of claim 5, wherein a positioning hole to which the column is insertion-fitted is formed at a central axis of the first shaft or a central axis of the second shaft.

8. The transfer device of claim 5, wherein the column is provided with a length adjustment unit for adjusting a length of the column.

9. The transfer device of claim 8, wherein an openable and closable window is provided at the ceiling portion of the transfer chamber.

10. The transfer device of claim 1, wherein each of the first and the second pick is provided with collision preventing members for preventing collision between the target object held by the first pick and the target object held by the second pick.

11. A target object processing apparatus for processing a target object, wherein the transfer device of claim 1 is used to transfer the target object.
